(19) United States
(12) Patent Application Publication
(10) Pub. No.: US 2017/0053779 A1
(43) Pub. Date: Feb. 23, 2017

(54) SUBSTRATE PROCESSING APPARATUS AND SUBSTRATE PROCESSING METHOD

(71) Applicant: Shibaura Mechatronics Corporation, Yokohama-shi (JP)

(72) Inventors: Kazuki Nakazawa, Yokohama (JP); Hiroki Shirahama, Yokohama (JP); Yoshie Okamoto, Yokohama (JP)

(21) Appl. No.: 15/239,871

(22) Filed: Aug. 18, 2016

(30) Foreign Application Priority Data
Aug. 19, 2015 (JP) 2015-161760

(51) Int. Cl. H01J 37/32; C23C 16/50

(52) U.S. Cl. CPC H01J 37/32009; C23C 16/50; H01J 2237/334

(57) ABSTRACT

According to one embodiment, a substrate processing apparatus includes a processor, a transferring part, a load lock unit, and a transfer unit. The processor performs processing of a substrate in an atmosphere. The transferring part transfers the substrate in an environment having a pressure higher than the pressure when performing the processing. The load lock unit is provided between the processor and the transferring part. The transfer unit is provided between the load lock unit and the processor. The load lock unit includes a supporter, and a drive unit. The supporter supports the substrate. The drive unit moves a position in a rotation direction of the supporter. The transfer unit transfers the substrate from the processor to the supporter partway through the processing of the substrate in the processor. The drive unit moves a position in a rotation direction of the transferred substrate.

### CROSS-REFERENCE TO RELATED APPLICATIONS

This application is based upon and claims the benefit of priority from Japanese Patent Application No. 2015-161760, filed on Aug. 19, 2015; the entire contents of which are incorporated herein by reference.

### BACKGROUND

Field

Embodiments described herein relate generally to a substrate processing apparatus and a substrate processing method.

Description of the Related Art

Processing such as etching, ashing, vapor deposition, film formation, etc., are performed by plasma processing or processing using a processing gas for a substrate such as a semiconductor wafer, a flat panel display substrate, an exposure mask substrate, a nanoimprint substrate, etc., and for films or the like formed on the substrate.

Technology has been proposed in which the configuration of the placement surface of a placement unit that holds the substrate is matched to the configuration of the back surface of the substrate to reduce the bias of the amount of processing in the surface of the substrate (e.g., refer to JP 2013-206971A).

However, in the interior of the processing container when performing the processing of the substrate, there may be a bias in the horizontal distribution of the plasma density or a bias in the horizontal distribution of the processing gas concentration.

Therefore, there are cases where it is difficult to reduce the bias of the amount of processing in the surface of the substrate using static conditions such as the configuration of the placement surface, etc.

Therefore, it is desirable to develop technology in which the bias of the amount of processing in the surface of the substrate can be reduced.

### SUMMARY

In general, according to one embodiment, a substrate processing apparatus includes a processor, a transferring part, a load lock unit, and a transfer unit.

The processor performs processing of a substrate in an atmosphere. The atmosphere is depressurized from atmospheric pressure.

The transferring part transfers the substrate in an environment having a pressure higher than the pressure when performing the processing.

The load lock unit is provided between the processor and the transferring part.

The transfer unit is provided between the load lock unit and the processor.

The load lock unit includes a supporter, and a drive unit. The supporter supports the substrate. The drive unit moves a position in a rotation direction of the supporter.

The transfer unit transfers the substrate from the processor to the supporter partway through the processing of the substrate in the processor.

The drive unit moves a position in a rotation direction of the transferred substrate.

### BRIEF DESCRIPTION OF THE DRAWINGS

FIG. 1 is a layout diagram showing the substrate processing apparatus 1 according to the embodiment;

FIG. 2 is a schematic cross-sectional view showing an example of the processor 50;

FIGS. 3A and 3B are schematic cross-sectional views showing the load lock unit 30;

FIG. 4 is a line B-B auxiliary cross-sectional view of FIGS. 3A and 3B;

FIG. 5 is a flowchart showing the transfer method of the substrate W from the container 11 to the processor 50;

FIG. 6 is a flowchart showing the transfer method of the substrate W between the processor 50 and the load lock unit 30;

FIG. 7 is a flowchart showing the transfer method of the substrate W from the processor 50 to the container 11;

FIG. 8 shows the distribution of the etching amount in the case where the position in the rotation direction of the substrate W is not moved; and

FIG. 9 shows the distribution of the etching amount in the case where the position in the rotation direction of the substrate W is moved.

### DETAILED DESCRIPTION

Embodiments will now be described with reference to the drawings.

Similar components in the drawings are marked with the same reference numerals; and a detailed description is omitted as appropriate. A substrate processing apparatus 1 according to an embodiment of the invention may be a plasma processing apparatus that utilizes plasma, a processing apparatus or the like that uses a processing gas, a processing liquid, etc.

However, in the case of a plasma processing apparatus, a bias of the amount of processing occurs easily in the surface of the substrate because a bias occurs easily in the horizontal distribution of the plasma density.

Therefore, a case will now be described where the substrate processing apparatus 1 according to the embodiment of the invention is an apparatus utilizing plasma.

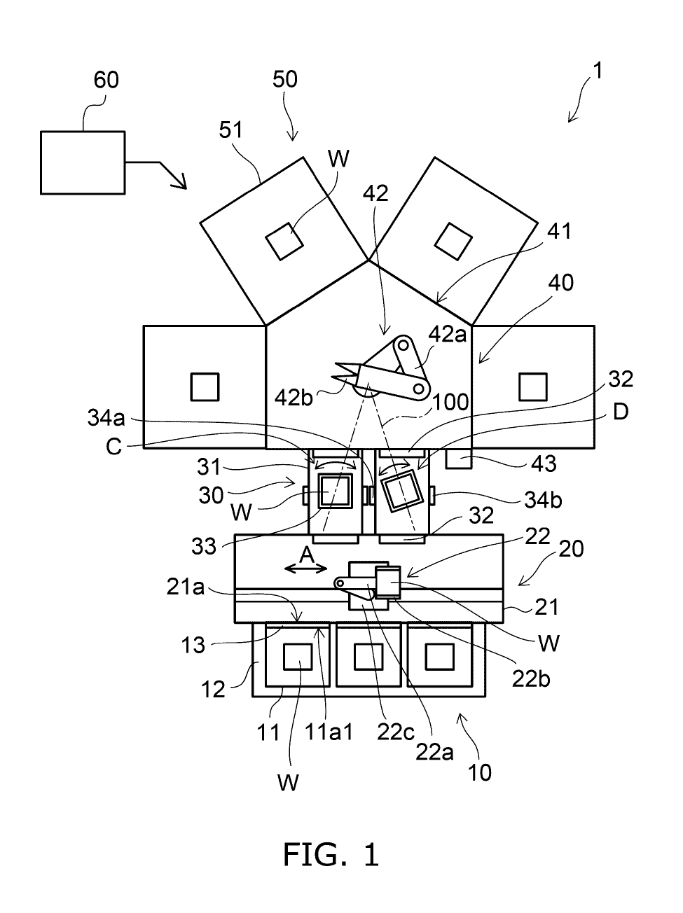

FIG. 1 is a layout diagram showing the substrate processing apparatus 1 according to the embodiment.

As shown in FIG. 1, an accumulator 10, a transferring part 20, a load lock unit 30, a transfer unit 40, a processor 50, and a controller 60 are provided in the substrate processing apparatus 1.

The planar configuration of a substrate W on which processing is performed by the substrate processing apparatus 1 is a quadrilateral. Although the material of the substrate W is not particularly limited, the material of the substrate W may be, for example, quartz, glass, etc. Although the applications of the substrate W are not particularly limited, the substrate W may be, for example, a flat panel display substrate, an exposure mask substrate, a nanoimprint substrate, etc.

A container 11, a stand 12, and an opening/closing door 13 are provided in the accumulator 10.

The container 11 stores the substrate W.

Although the number of the containers 11 is not particularly limited, the productivity can be increased by providing multiple containers 11. In the case where the multiple containers 11 are provided, the multiple containers 11 that have similar configurations may be provided; or the multiple containers 11 that have different configurations may be provided. The container 11 may be, for example, a carrier in which the substrates W are storable in a stacked configuration (a multiple level configuration), etc. For example, the container 11 may be a FOUP (Front-Opening Unified Pod) or the like which is a front-opening carrier for transferring and storing the substrates and is used in mini-environment type semiconductor plants.

However, the container 11 is not limited to a FOUP or the like; and it is sufficient to be able to store the substrate W.

The stand 12 is provided at the side surface of a housing 21 or on the floor surface. The container 11 is placed on the upper surface of the stand 12. The stand 12 holds the container 11 that is placed.

The opening/closing door 13 is provided between an opening 11a1 of the container 11 and an opening 21a of the housing 21 of the transferring part 20. The opening/closing door 13 opens and closes the opening 11a1 of the container 11. For example, the opening 11a1 of the container 11 is closed by raising the opening/closing door 13 by a not-shown drive unit. The opening 11a1 of the container 11 is opened by lowering the opening/closing door 13 by the not-shown drive unit.

The transferring part 20 is provided between the accumulator 10 and the load lock unit 30.

The transferring part 20 transfers the substrate W in an environment having a pressure (e.g., atmospheric pressure) that is higher than the pressure when performing the processing.

The housing 21 and a transferer 22 are provided in the transferring part 20.

The housing 21 has a box configuration; and the transferer 22 is provided in the interior of the housing 21. The housing 21 may be, for example, a housing that has an airtight structure such that particles from the outside, etc., cannot enter. The atmosphere of the interior of the housing 21 is, for example, atmospheric pressure.

The transferer 22 conveys and transfers the substrate W between the accumulator 10 and the load lock unit 30.

The transferer 22 may be a transfer robot having an arm 22a that rotates with a rotation axis as the center.

For example, the transferer 22 includes a mechanism in which a timing belt, links, etc., are combined. The arm 22a has a joint. A holder 22b that holds the substrate W is provided at the tip of the arm 22a.

A movement unit 22c is provided below the arm 22a. The movement unit 22c is movable in a transfer direction A (the direction of arrow A). Also, a not-shown position adjuster that moves the position in the rotation direction of the substrate W and the position in the lifting/lowering direction of the substrate W, a not-shown direction converter that changes the direction of the arm 22a, etc., are provided.

Therefore, the transfer of the substrate W to the container 11 or a load lock chamber 31 can be performed by the holder 22b holding the substrate W, by moving the substrate W in the direction of arrow A while being held, by changing the direction of the arm 22a, and by causing the arm 22a to extend and retract by bending.

The load lock unit 30 is provided between the transferring part 20 and the processor 50.

The load lock unit 30 can transfer the substrate W between the transferring part 20 side where the atmosphere is, for example, atmospheric pressure and the transfer unit 40 side where the atmosphere is, for example, the pressure when performing the processing.

As described below, the load lock unit 30 includes a mechanism that moves the position in the rotation direction of the substrate W.

Therefore, the load lock unit 30 can move the position in the rotation direction of the substrate W.

The movement of the position in the rotation direction of the substrate W is, for example, the action of rotating the substrate W a prescribed angle.

The load lock unit 30 further has a configuration that can suppress the adhesion of particles to the substrate W.

Details relating to the load lock unit 30 are described below.

The transfer unit 40 is provided between the processor 50 and the load lock unit 30. The transfer unit 40 transfers the substrate W between the processor 50 and the load lock unit 30. A housing 41, a transferer 42, and a depressurization unit 43 are provided in the transfer unit 40.

The housing 41 has a box configuration; and the interior of the housing 41 communicates with the interior of the load lock chamber 31 via an opening/closing door 32. The housing 41 can maintain an atmosphere depressurized from atmospheric pressure.

The transferer 42 is provided in the interior of the housing 41.

An arm 42a that has a joint is provided in the transferer 42. A holder 42b that holds the substrate W is provided at the tip of the arm 42a.

The transferer 42 performs the transfer of the substrate W between the load lock chamber 31 and a processing container 51 by the substrate W being held by the holder 42b, by changing the direction of the arm 42a, and by causing the arm 42a to extend and retract by bending.

The depressurization unit 43 depressurizes the atmosphere of the interior of the housing 41 to a prescribed pressure that is lower than atmospheric pressure. For example, the depressurization unit 43 causes the pressure of the atmosphere of the interior of the housing 41 to be substantially equal to the pressure of the processing container 51 when performing the processing.

The processor 50 performs the desired processing of the substrate W placed in the interior of the processing container 51.

For example, the processor 50 performs plasma processing of the substrate W in an atmosphere depressurized from atmospheric pressure.

The processor 50 may be, for example, a plasma processing apparatus such as a plasma etching apparatus, a plasma ashing apparatus, a sputtering apparatus, a plasma CVD apparatus, etc.

In such a case, the method for generating the plasma is not particularly limited; and, for example, the plasma may be generated using a high frequency wave, a microwave, etc.

However, the type and plasma generation method of the plasma processing apparatus are examples and are not limited thereto.

It is sufficient for the processor 50 to perform the processing of the substrate W in an atmosphere depressurized from atmospheric pressure.

The number of the processors 50 also is not particularly limited. In the case where the processor 50 is multiply provided, the same type of substrate processing apparatus may be provided; or different types of substrate processing apparatuses may be provided. In the case where the same type of substrate processing apparatus is multiply provided, the processing conditions may be set to be different; or the processing conditions may be set to be the same.

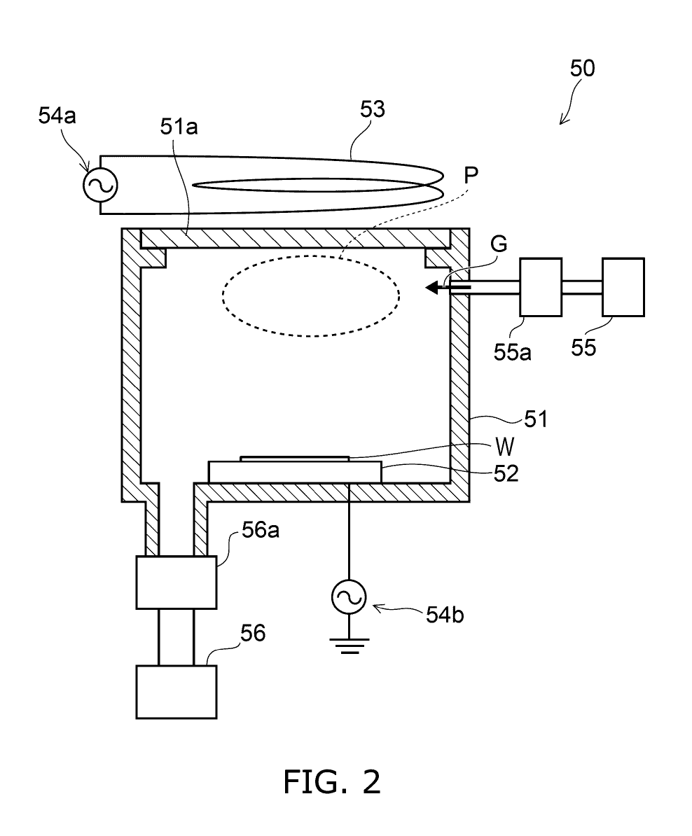

FIG. 2 is a schematic cross-sectional view showing an example of the processor 50.

The processor 50 shown in FIG. 2 is an inductively coupled plasma processing apparatus. Namely, the processor 50 is an example of a plasma processing apparatus that processes the substrate W by using plasma excited and generated by high frequency energy to produce plasma products from a process gas.

As shown in FIG. 2, the processor 50 includes the processing container 51, a placement unit 52, a plasma generation antenna 53, high frequency wave generators 54a and 54b, a gas supply unit 55, a depressurization unit 56, etc. Also, a not-shown controller that controls each component included in the processor 50 such as the high frequency wave generators 54a and 54b, the gas supply unit 55, the depressurization unit 56, etc., a not-shown operation unit that operates each component, etc., are provided.

The plasma generation antenna 53 generates plasma P by supplying high frequency energy (electromagnetic energy) to a region where the plasma P is generated.

The plasma generation antenna 53 supplies the high frequency energy to the region where the plasma P is generated via a transmissive window 51a. The transmissive window 51a has a flat plate configuration and is made of a material that has a high transmittance for the high frequency energy and is not easily etched. The transmissive window 51a is provided to be airtight at the upper end of the processing container 51.

In such a case, the plasma generation antenna 53, the high frequency wave generators 54a and 54b, etc., are used as a plasma generation unit that supplies the electromagnetic energy to the region where the plasma is generated.

The gas supply unit 55 is connected to the side wall upper portion of the processing container 51 via a mass flow controller (MFC) 55a. A process gas G can be supplied to the region where the plasma P is generated inside the processing container 51 from the gas supply unit 55 via the mass flow controller 55a.

The processing container 51 has a substantially cylindrical configuration having a bottom and can maintain an atmosphere depressurized from atmospheric pressure. The placement unit 52 is provided in the interior of the processing container 51.

The substrate W is placed on the upper surface of the placement unit 52.

In such a case, the substrate W may be placed directly on the upper surface of the placement unit 52 or may be placed on the upper surface of the placement unit 52 with a not-shown support member or the like interposed.

The depressurization unit 56 such as a turbo molecular pump (TMP) or the like is connected to the bottom surface of the processing container 51 via an auto pressure controller (APC) 56a. The depressurization unit 56 depressurizes the interior of the processing container 51 to a prescribed pressure. The auto pressure controller 56a controls the internal pressure of the processing container 51 to be the prescribed pressure based on the output of a not-shown pressure gauge that senses the internal pressure of the processing container 51.

When performing the plasma processing of the substrate W, the interior of the processing container 51 is depressurized to the prescribed pressure by the depressurization unit 56; and a prescribed amount of the process gas G (e.g., CF₄, etc.) is supplied from the gas supply unit 55 to the region where the plasma P is generated inside the processing container 51. On the other hand, high frequency power having a prescribed power is applied to the plasma generation antenna 53 from the high frequency wave generator 54a; and electromagnetic energy is radiated into the interior of the processing container 51 via the transmissive window 51a. An electric field that accelerates ions from the plasma P toward the substrate W is formed at the placement unit 52 holding the substrate W by applying high frequency power having a prescribed power from the high frequency wave generator 54b.

Thus, the plasma P is generated by the electromagnetic energy radiated into the interior of the processing container 51 and the electromagnetic energy from the placement unit 52; and the process gas G is excited and activated to produce plasma products such as neutral active species, ions, etc., inside the generated plasma P. Then, the front surface of the substrate W is processed by the plasma products that are produced.

The controller 60 controls the operation of each component provided in the substrate processing apparatus 1.

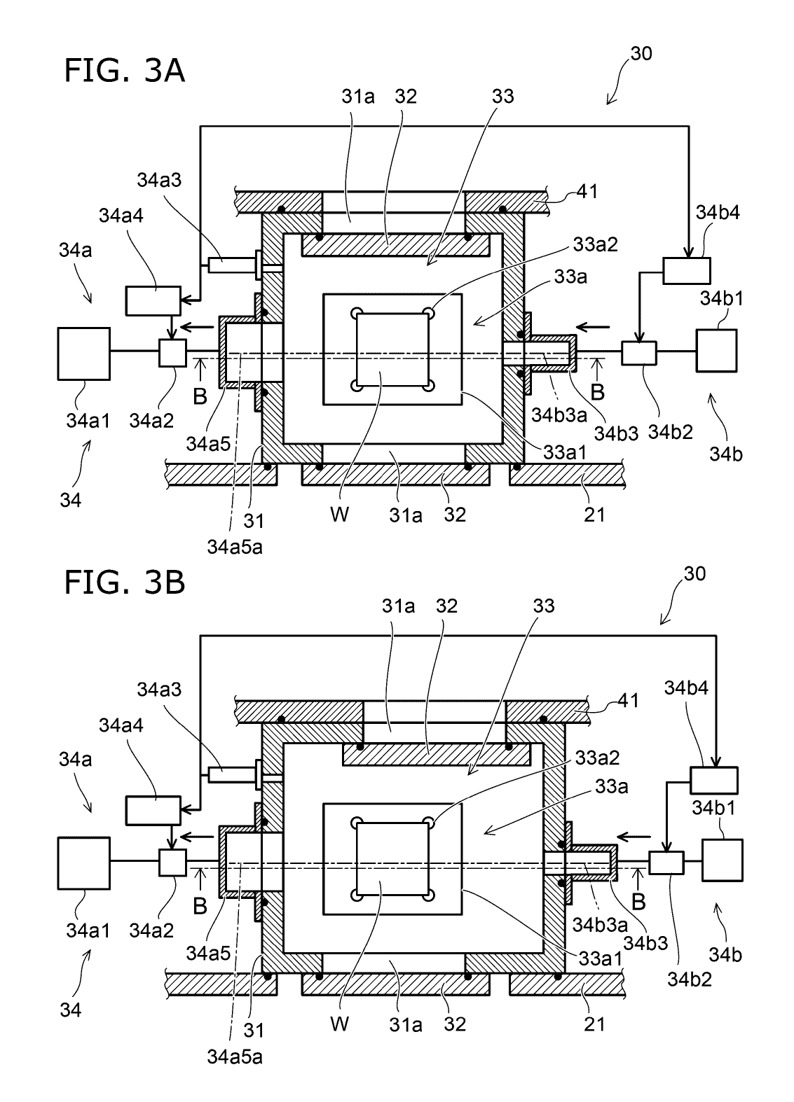

The controller 60 controls the operation of each component such as, for example, the opening and closing of the opening/closing door 13, the conveyance and transfer of the substrate W by the transferer 22, the opening and closing of the opening/closing door 32, the pressure control by a pressure controller 34 (referring to FIGS. 3A and 3B), the transfer of the substrate W by the transferer 42, the depressurization by the depressurization unit 43, various processing by the processor 50, etc.

The load lock unit 30 will now be described further.

FIGS. 3A and 3B are schematic cross-sectional views showing the load lock unit 30.

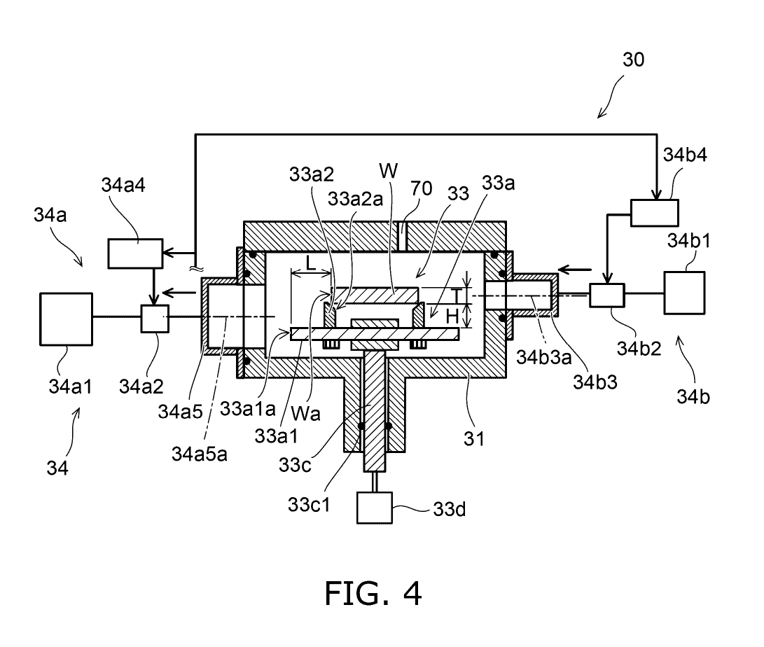

FIG. 4 is a line B-B auxiliary cross-sectional view of FIGS. 3A and 3B.

As shown in FIGS. 3A and 3B and FIG. 4, the load lock chamber 31, the opening/closing doors 32, a placement unit 33, and the pressure controller 34 are provided in the load lock unit 30.

The load lock chamber 31 has a box configuration and can maintain an atmosphere depressurized from atmospheric pressure.

The opening/closing doors 32 are provided respectively on the housing 21 side (the transferring part 20 side) and the housing 41 side (the transfer unit 40 side) of the load lock chamber 31. Openings 31a of the load lock chamber 31 can be opened and closed by not-shown drive units moving the opening/closing doors 32.

As shown in FIG. 3B, the position of the opening 31a on the transferer 42 side may be shifted from the position of the opening 31a on the transferer 22 side when the load lock chamber 31 is viewed in plan.

In such a case, the center of the opening 31a on the transferer 42 side may be shifted more toward the center of the transferer 42 than is the center of the opening 31a on the transferer 22 side. Thus, the transferer 42 can easily enter the opening 31a when transferring the substrate W between the transferer 42 and the load lock chamber 31.

The placement unit 33 is provided in the interior of the load lock chamber 31. The substrate W is placed on the placement unit 33 in a horizontal state. The placement unit 33 supports the substrate W that is placed.

The placement unit 33 moves the position in the rotation direction of the substrate W that is placed.

A supporter 33a, a rotation axis 33c, and a drive unit 33d are provided in the placement unit 33. The supporter 33a includes a support plate 33a1 and a support body 33a2.

The support plate 33a1 is provided in the interior of the load lock chamber 31. The support plate 33a1 has a flat plate configuration. The size of the major surface of the support plate 33a1 is larger than the size of the substrate W. As shown in FIG. 4, the major surface of the support plate 33a1 on the substrate W side faces the substrate W supported by the support body 33a2.

The support body 33a2 has a columnar configuration; and an oblique surface 33a2a for supporting the substrate W is provided at one end portion of the support body 33a2. The other end portion side of the support body 33a2 is provided at the support plate 33a1. Four support bodies 33a2 are provided; and the oblique surfaces 33a2a of the support bodies 33a2 support the corners of the quadrilateral substrate W.

The contact surface area can be reduced by the oblique surfaces 33a2a of the support bodies 33a2 supporting the corners of the substrate W. Therefore, the occurrence of particles can be suppressed.

The alignment of the support position also can be performed by supporting the substrate W with the oblique surfaces 33a2a of the support bodies 33a2.

The rotation axis 33c has a columnar configuration; and one end portion of the rotation axis 33c is provided at the support plate 33a1. The other end portion of the rotation axis 33c is exposed outside the load lock chamber 31. A sealing member 33c1 such as an O-ring or the like is provided between the rotation axis 33c and the load lock chamber 31.

The drive unit 33d moves the position in the rotation direction of the support plate 33a1. Therefore, the position in the rotation direction of the substrate W can be moved using the drive unit 33d, the rotation axis 33c, the support plate 33a1, and the support body 33a2. The drive unit 33d may be, for example, a control motor such as a servo motor, etc.

The pressure controller 34 includes a depressurization unit 34a and a gas supply unit 34b.

The depressurization unit 34a exhausts the gas that is in the interior of the load lock chamber 31 and depressurizes the atmosphere of the interior of the load lock chamber 31 to a prescribed pressure that is lower than atmospheric pressure. For example, the pressure controller 34 causes the pressure of the atmosphere of the interior of the load lock chamber 31 to be substantially equal to the pressure of the atmosphere of the interior of the housing 41 (the pressure when performing the processing).

The gas supply unit 34b supplies a gas to the interior of the load lock chamber 31 and causes the pressure of the atmosphere of the interior of the load lock chamber 31 to be substantially equal to the pressure of the atmosphere of the interior of the housing 21. For example, the gas supply unit 34b supplies the gas to the interior of the load lock chamber 31 and returns the atmosphere of the interior of the load lock chamber 31 from the pressure lower than atmospheric pressure to, for example, atmospheric pressure.

Therefore, the substrate W can be transferred between the transferring part 20 and the transfer unit 40 by placing the substrate W on the upper surface of the placement unit 33 provided in the interior of the load lock chamber 31 and by changing the pressure of the atmosphere of the interior of the load lock chamber 31.

That is, the substrate W can be transferred between the transferring part 20 side where the atmosphere is, for example, atmospheric pressure and the transfer unit 40 side where the atmosphere is a pressure lower than atmospheric pressure.

An exhaust unit 34a1, a conductance controller 34a2, a sensor 34a3 (referring to FIGS. 3A and 3B), a controller 34a4, and a connection unit 34a5 are provided in the depressurization unit 34a.

The exhaust unit 34a1, the conductance controller 34a2, and the connection unit 34a5 are connected by pipes. The exhaust unit 34a1 communicates with the interior of the load lock chamber 31 via the conductance controller 34a2 and the connection unit 34a5.

The exhaust unit 34a1 exhausts the gas in the interior of the load lock chamber 31.

The exhaust unit 34a1 may be, for example, a vacuum pump, etc.

The conductance controller 34a2 controls conductance C (hereinbelow, called the conductance C of the exhaust system) that relates to the exhaust of the gas.

The conductance controller 34a2 may be, for example, a butterfly valve that controls the conductance by changing the rotation angle of a valve, etc.

The sensor 34a3 is provided at the side wall of the load lock chamber 31 and senses the pressure in the interior of the load lock chamber 31.

The sensor 34a3 may output an electrical signal corresponding to the pressure that is sensed. The sensor 34a3 may be, for example, a vacuum gauge, etc.

The controller 34a4 is electrically connected to the conductance controller 34a2 and the sensor 34a3.

The controller 34a4 controls the conductance controller 34a2 based on the electrical signal transmitted from the sensor 34a3.

In other words, the controller 34a4 controls the conductance C of the exhaust system based on the electrical signal transmitted from the sensor 34a3.

The controller 34a4 is not always necessary; and the conductance C of the exhaust system may be controlled by the controller 60.

The connection unit 34a5 is provided to be airtight at the opening provided in the side wall of the load lock chamber 31.

A supply unit 34b1, a conductance controller 34b2, a connection unit 34b3, and a controller 34b4 are provided in the gas supply unit 34b.

The supply unit 34b1, the conductance controller 34b2, and the connection unit 34b3 are connected by pipes.

The supply unit 34b1 communicates with the interior of the load lock chamber 31 via the connection unit 34b3 and the conductance controller 34b2.

The supply unit 34b1 supplies a gas to the interior of the load lock chamber 31.

The supply unit 34b1 may be, for example, a cylinder that stores pressurized nitrogen gas, pressurized inert gas, etc.

The conductance controller 34b2 is provided between the supply unit 34b1 and the connection unit 34b3 and controls conductance C1 according to the supply of the gas.

The conductance controller 34b2 may be, for example, a flow rate control valve, etc.

The connection unit 34b3 is provided to be airtight at the opening provided in the side wall of the load lock chamber 31.

The connection unit 34b3 and the connection unit 34a5 are provided to face each other when viewed in plan (referring to FIGS. 3A and 3B). Also, a central axis 34b3a of the connection unit 34b3 and a central axis 34a5a of the connection unit 34a5 are on the same straight line when viewed in plan.

The flow path cross-sectional area of the connection unit 34b3 (the cross-sectional area in a direction orthogonal to the flow direction of the flow path) is greater than the flow path cross-sectional area of the pipe linking the supply unit 34b1 and the connection unit 34b3. Therefore, the flow velocity of the gas supplied to the interior of the load lock chamber 31 can be set to be slow.

The controller 34b4 is electrically connected to the conductance controller 34b2 and the sensor 34a3.

The controller 34b4 controls the conductance controller 34b2 based on the electrical signal transmitted from the sensor 34a3.

In other words, the controller 34b4 controls the conductance C1 of the gas supply system based on the electrical signal transmitted from the sensor 34a3.

The controller 34b4 is not always necessary; and the conductance C1 of the gas supply system may be controlled by the controller 60.

Here, there are cases where particles occur when the drive unit 33d moves the position in the rotation direction of the substrate W.

Therefore, the load lock unit 30 has a configuration in which the particles that occur do not adhere easily to the substrate W.

For example, as shown in FIG. 4, the major surface of the support plate 33a1 is provided to be parallel to the flow direction of the air flow formed in the interior of the load lock chamber 31 by the depressurization unit 34a and the gas supply unit 34b.

The connection unit 34b3 and the connection unit 34a5 are provided to face each other when viewed in plan. Also, the central axis 34b3a of the connection unit 34b3 and the central axis 34a5a of the connection unit 34a5 are on the same straight line when viewed in plan.

Therefore, the floating around of the particles can be suppressed because the turbulence of the flow of the air flow can be suppressed.

The size of the major surface of the support plate 33a1 is larger than the size of the substrate W.

Therefore, even if the particles on the bottom surface side of the load lock chamber 31 float around, the entrance to the substrate W side of the particles that float around can be suppressed.

Eddies are generated when the air flow contacts the support plate 33a1 and/or the support body 33a2 provided in the interior of the load lock chamber 31. When the eddies are generated, particles are trapped in the eddies that are generated; and the particles are not easily exhausted outside the load lock chamber 31.

Therefore, the support plate 33a1 and/or the support body 33a2 have configurations such that the eddies are not generated easily.

For example, because the major surface of the support plate 33a1 is a flat surface, the air resistance is low; and the generation of the eddies can be suppressed.

For example, because the support body 33a2 has the columnar configuration, the air resistance is low; and the generation of the eddies can be suppressed. In such a case, the generation of the eddies can be even lower by setting the cross-sectional configuration of the support body 33a2 to be a circle, an ellipse, etc.

As described above, because the major surface of the support plate 33a1 is provided to be parallel to the flow direction of the air flow, the air resistance is low; and the generation of the eddies can be suppressed.

The positional relationship between the substrate W and the support plate 33a1 is as follows.

For example, as shown in FIG. 4, a dimension H between the substrate W and the support plate 33a1 and a thickness dimension T of the substrate W are set to satisfy the following Formula (1).

H≧T (1)

Thus, because the increase of the flow velocity of the air flow flowing through the support plate 33a1 side of the substrate W can be suppressed, the particles do not float around easily. Also, the difference between the flow velocity of the air flow flowing through the support plate 33a1 side of the substrate W and the flow velocity of the air flow flowing through the side (the ceiling plate side) opposite to the support plate 33a1 side of the substrate W can be reduced. Therefore, because the difference of the pressure between the support plate 33a1 side and ceiling plate side of the substrate W can be reduced, the shift of the position of the substrate W can be suppressed.

The dimension H between the substrate W and the support plate 33a1 and a dimension L between an end portion Wa of the substrate W on the downstream side of the exhaust and an end portion 33a1a of the support plate 33a1 on the downstream side of the exhaust are set to satisfy the following Formula (2).

L≧H (2)

Thus, a distance can be provided between the eddy generated at the end portion Wa vicinity on the downstream side of the substrate W and the eddy generated at the end portion 33a1a vicinity on the downstream side of the support plate 33a1; therefore, interference between the eddies that are generated can be suppressed. Therefore, the growth of the eddies due to the interference between the eddies can be suppressed.

Thus, the particles on the bottom side of the load lock chamber 31 do not float around easily.

Therefore, even if particles occur when the drive unit 33d moves the position in the rotation direction of the substrate W, the adhesion of the particles to the substrate W can be suppressed.

The processes of depressurizing and moving the position in the rotation direction of the substrate W may be performed simultaneously. Thereby, the particles that occur from the drive unit 33d when rotating the substrate W are exhausted when performing the depressurization; therefore, the adhesion of the particles to the substrate W can be suppressed.

Convection currents do not occur in a vacuum. Therefore, the particles do not adhere to the substrate W because the particles do not float around. Therefore, in the case where the rotation of the substrate W partway through the processing is performed in the interior of the load lock unit 30 already in the vacuum state, the depressurization may not be performed.

An example of the effects of the substrate processing apparatus 1 and the substrate processing method according to the embodiment will now be described.

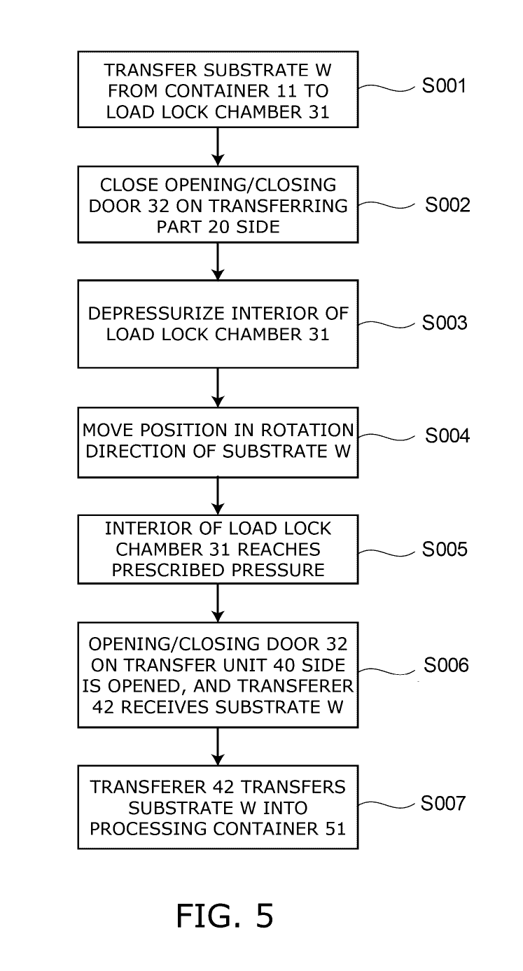

FIG. 5 is a flowchart showing the transfer method of the substrate W from the container 11 to the processor 50.

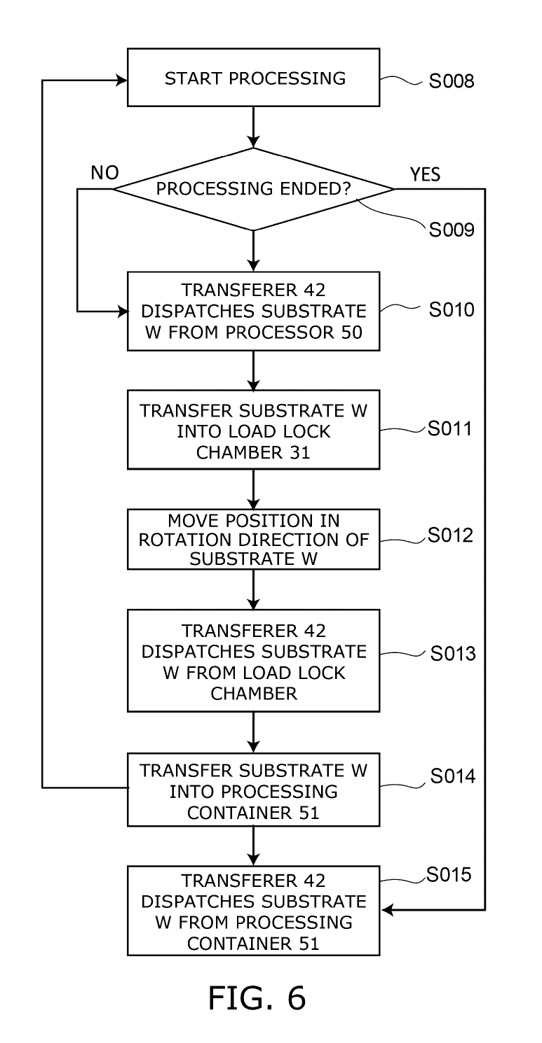

FIG. 6 is a flowchart showing the transfer method of the substrate W between the processor 50 and the load lock unit 30.

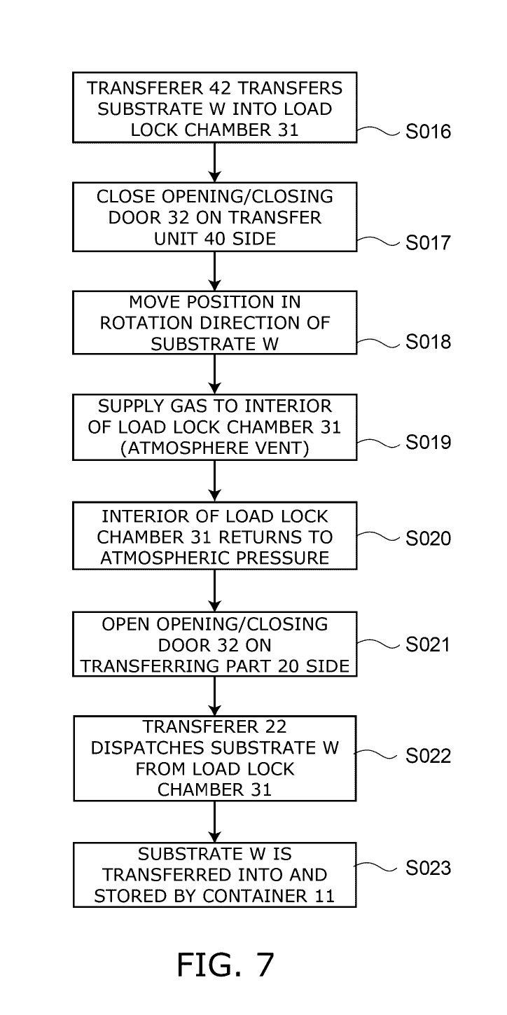

FIG. 7 is a flowchart showing the transfer method of the substrate W from the processor 50 to the container 11.

First, the substrate W is transferred from the container 11 to the load lock chamber 31 (S001 of FIG. 5).

For example, the transferer 22 removes the substrate W from the container 11 and places the substrate W on the placement unit 33 in the interior of the load lock chamber 31.

Then, the opening/closing door 32 of the load lock chamber 31 is closed; and the depressurization unit 34a depressurizes the interior of the load lock chamber 31 to the prescribed pressure (S002 and S003 of FIG. 5).

Then, the drive unit 33d moves the position in the rotation direction of the substrate W using the rotation axis 33c, the support plate 33a1, and the support body 33a2 (S004 of FIG. 5).

As shown in portion C of FIG. 1, the direction in which the side of the substrate W transferred between the transferer 22 and the placement unit 33 extends is parallel or perpendicular to the transfer direction A.

On the other hand, as shown in portion D of FIG. 1, the direction in which the side of the substrate W transferred between the transferer 42 and the placement unit 33 extends is parallel or perpendicular to a line 100 connecting the center of the transferer 42 and the center of the placement unit 33.

The center of the transferer 42 is the center of the rotation axis of the transferer 42; and the center of the placement unit 33 is the center of the rotation axis 33c.

Therefore, when transferring the substrate W between the transferer 22 and the placement unit 33, the drive unit 33d moves the position in the rotation direction of the substrate W that is held by the support body 33a2 so that the extension direction of the side of the substrate W that is held is parallel or perpendicular to the transfer direction A of the transferring part 20.

When transferring the substrate W between the transferer 42 and the placement unit 33, the drive unit 33d moves the position in the rotation direction of the substrate W that is held by the support body 33a2 so that the extension direction of the side of the substrate W that is held is parallel or perpendicular to the line connecting the center of the transfer unit 40 (the transferer 42) and the center of the placement unit 33.

The center of the transfer unit 40 (the transferer 42) is the rotation center (the axis) of the transfer arm used as the transferer 42; and the center of the region where a support body 33b is provided is the center of the substrate W.

Thus, a smooth transfer of the substrate W can be performed.

Because the position in the rotation direction of the substrate W can be changed in the load lock unit 30, the arrangement angles with respect to the load lock unit 30 of the transferring part 20 and/or the transfer unit 40 that is adjacent to the load lock unit 30 can be set as desired.

Therefore, because the degrees of freedom relating to the arrangement of the transferring part 20, the load lock unit 30, and the transfer unit 40 are high, the substrate processing apparatus 1 can be downsized; and even the mounting surface area can be reduced.

When the pressure inside the load lock chamber 31 reaches the prescribed pressure, the opening/closing door 32 on the transfer unit 40 side of the load lock chamber 31 is opened; and the transferer 42 receives the substrate W placed on the placement unit 33 (the support body 33a2) (S005 and S006 of FIG. 5).

Then, the transferer 42 transfers the substrate W into the interior of the processing container 51 by changing the direction of the arm 42a and causing the arm 42a to extend and retract by bending. The substrate W that is transferred into the interior of the processing container 51 is transferred to the placement unit 52 of the processor 50 (S007 of FIG. 5). Then, the processor 50 performs the prescribed processing of the substrate W (S008 of FIG. 6).

Here, when performing the plasma processing of the substrate W, there are cases where there is a bias in the horizontal distribution of the plasma density in the interior of the processing container 51.

In particular, it is difficult to change the distribution of the plasma density in the case where the central region of the substrate W does not match the region where the horizontal distribution of the plasma density has the highest density.

If the processing of the substrate W is performed in the state in which there is a bias in the horizontal distribution of the plasma density, the amount of processing is biased in the surface of the substrate W. Therefore, if the processing is completed in the state in which there is a bias in the horizontal distribution of the plasma density, there is a risk that the bias of the amount of processing in the surface of the substrate W may increase.

For example, in the case of plasma etching, the depth dimensions of the trenches and the depth dimensions of the holes may differ greatly between the regions on the substrate W.

Therefore, the transfer unit 40 (the transferer 42) transfers the substrate W from the processor 50 (the processing container 51) to the load lock unit 30 (the support body 33a2) partway through the processing of the processor 50 (the processing container 51) (S009 to S011 of FIG. 6).

“Partway through the processing” may be a point in time when a constant amount of time has elapsed from the start of the processing of the substrate W but before it is determined that the processing has completed. For example, the determination of the completion of the processing may be performed indirectly using the elapse of a preset processing time or may be performed directly by detecting the end point by measuring the etching depth using an optical sensor, etc.

When the substrate W is transferred to the load lock unit 30, the drive unit 33d moves the position in the rotation direction of the substrate W that is transferred (S012 of FIG. 6).

At this time, the drive unit 33d moves the position 90°×n (n being a natural number) in the rotation direction of the substrate W that is transferred.

Continuing, the transfer unit 40 (the transferer 42) removes, from the load lock chamber 31, the substrate W having the moved position in the rotation direction and places the substrate W on the placement unit 52 provided in the interior of the processor 50 (the processing container 51) (S013 and S014 of FIG. 6).

Continuing, the processor 50 performs the remaining processing of the substrate W.

In other words, the processing is started again (returning to S008 of FIG. 6).

The method described above may be repeated until it is determined that the processing has completed. In the case where it is determined that the processing has completed, the transferer 42 dispatches the substrate W from the processor 50 (the processing container 51) (S015 of FIG. 6).

In other words, in the process of performing the processing of the substrate W, the position in the rotation direction of the substrate W is moved partway through the processing (before the prescribed processing is completed) so that uniform processing has been performed when the prescribed processing is completed.

The effects of moving the position in the rotation direction of the substrate W partway through the processing process are described below.

Then, the transferer 42 removes the substrate W having the completed processing from the interior of the processing container 51 and places the substrate W on the placement unit 33 (the support body 33a2) provided in the interior of the load lock chamber 31 (S016 of FIG. 7).

The transferer 42 receives the substrate W of the next processing from the placement unit 33 (the support body 33a2) and transfers the substrate W into the interior of the processing container 51.

The substrate W that has the completed processing and is placed on the placement unit 33 (the support body 33a2) is stored in the container 11 by the reverse method of the method described above.

Specifically, the opening/closing door 32 of the load lock chamber 31 is closed after the substrate W is transferred by the transferer 42 into the load lock chamber 31 (S017 of FIG. 7).

Then, the position in the rotation direction of the substrate W is moved (S018 of FIG. 7).

Continuing, the gas supply unit 34b supplies a gas to the interior of the load lock chamber 31 and returns the atmosphere of the interior of the load lock chamber 31 from the pressure lower than atmospheric pressure to, for example, atmospheric pressure (S019 of FIG. 7).

At this time, the particles that are in the interior of the load lock chamber 31 are caused not to float around due to the gas that is supplied.

Details relating to the supply of the gas to the interior of the load lock chamber 31 are described below.

Then, after the load lock chamber 31 is returned to atmospheric pressure, the opening/closing door 32 of the transferring part 20 is opened (S020 and S021 of FIG. 7).

Continuing, the transferer 22 dispatches the substrate W from the load lock chamber 31 and stores the substrate W in the container 11 (S022 and S023 of FIG. 7).

On the other hand, the next substrate W that is transferred into the interior of the processing container 51 is transferred to the placement unit 52 of the processing container 51 interior (referring to FIG. 2). Subsequently, the prescribed processing of the substrate W is performed by the method described above.

As necessary, the substrate W may be processed continuously by repeating the method described above.

As described above, the substrate processing method according to the embodiment may include the following processes:

a process of performing the processing of the substrate W in a first environment depressurized from atmospheric pressure;

a process of moving, in the process of performing the processing of the substrate W, the substrate W to a second environment from the first environment partway through the processing, where the second environment is separated from the first environment and has a pressure not more than the pressure of the first environment;

a process of moving the position in the rotation direction of the substrate W in the second environment; and

a process of continuing the remaining discontinued processing of the substrate W after moving the position in the rotation direction of the substrate W.

The position in the rotation direction of the substrate W may be moved 90°×n (n being a natural number) in the process of moving the position in the rotation direction of the substrate W.

The effects of moving the position in the rotation direction of the substrate W will now be described.

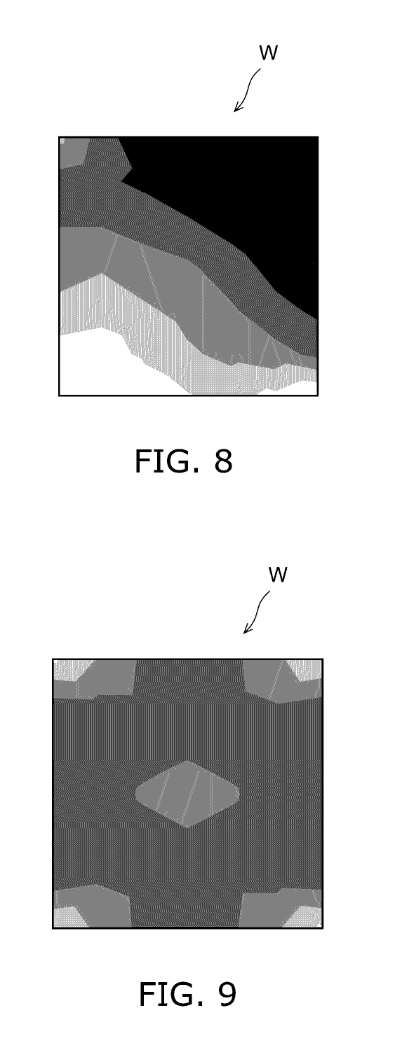

FIG. 8 shows the distribution of the etching amount in the case where the position in the rotation direction of the substrate W is not moved.

FIG. 9 shows the distribution of the etching amount in the case where the position in the rotation direction of the substrate W is moved.

FIG. 9 is the case where the position in the rotation direction of the substrate W is moved 90° three times. In FIG. 8 and FIG. 9, the distribution of the etching amount is shown as monotone shading that is lighter as the etching amount increases and darker as the etching amount decreases.

It can be seen from FIG. 8 that in the case where the position in the rotation direction of the substrate W is not moved, the bias of the etching amount in the surface of the substrate W is large.

In such a case, the depth dimensions of the trenches and the depth dimensions of the holes are shallow in the regions where the monotone color is dark. The depth dimensions of the trenches and the depth dimensions of the holes are deeper in the regions where the monotone color is light.

Conversely, it can be seen from FIG. 9 that in the case where the position in the rotation direction of the substrate W is moved 90° three times, the bias of the etching amount in the surface of the substrate W can be reduced.

According to knowledge obtained by the inventors, the fluctuation of the amount of processing when the position in the rotation direction of the substrate W is moved can be suppressed to ⅓ or less of the fluctuation of the amount of processing when the position in the rotation direction of the substrate W is not moved.

Although the case is shown where the position in the rotation direction of the substrate W is moved 90° three times, this is not limited thereto.

For example, the rotation angle, the rotation direction, the number of movements, etc., may be determined to reduce the bias of the amount of processing based on the distribution of the amount of processing determined by experiments, simulations, etc., beforehand.

For example, 0°→180°, 0°→90°→270°, or 0°→90°→−180° (a reverse rotation) may be used.

The rotation angle, the rotation direction, and the number of movements are not limited to those illustrated.

The movement of the position in the rotation direction of the substrate W may be performed based on the distribution of the amount of processing or may be performed without being based on the distribution of the amount of processing. In such a case, the movement of the position in the rotation direction of the substrate W may be performed at a predetermined timing or may be performed using prescribed conditions registered in a recipe, etc. Conditions such as the rotation angle, the rotation direction, the number of movements, etc., may be pre-registered in the recipe.

As shown in FIG. 4, a sensor 70 that senses the distribution of the amount of processing may be provided. For example, the sensor 70 is provided at the ceiling of the load lock chamber 31 and can sense the height level of the front surface of the substrate W. Sensing windows may be provided in the ceiling and side surface of the load lock chamber 31 and the bottom surface of the support plate 33a1; and the sensor 70 may be provided outside the sensing windows. The sensor 70 may be provided in the environment outside the load lock chamber 31 (e.g., the processing container 51 or the transferer 42). For example, the sensor 70 may be an interferometer, etc.

In such a case, the distribution of the amount of processing can be sensed by sensing the position of the front surface of the substrate W while moving the substrate W in the rotation direction. At this time, the sensor 70 may be moved in a direction parallel to the front surface of the substrate W. Thus, the distribution of the amount of processing in the entire region of the substrate W can be sensed.

Or, the substrate W may be fixed; light may be irradiated on one point or multiple points of the substrate W; and the amount of processing may be measured by sensing the intensity of the coherent light.

Or, the distribution of the amount of processing may be measured by scanning a stylus in contact with the front surface of the substrate W.

Thus, the distribution of the amount of processing can be sensed in the entire region of the substrate W.

The substrate W after the position in the rotation direction is moved may be transferred into the same processing container 51 as the processing container 51 of the processing prior to the rotational movement. Thus, the processing after the rotational movement can be performed in the same environment as the processing container 51 of the processing prior to the rotational movement.

The amount of processing changes according to the temperature of the substrate W. For example, if the substrate W is at a high temperature, the amount of processing is large; and if the substrate W is at a low temperature, the amount of processing is small. Therefore, it is favorable for the temperature of the substrate W to be about the same between the processing start time prior to the rotational movement and the processing start time after the rotational movement. The temperature of the substrate W after the rotational movement decreases when dispatched outside the processing container 51. Therefore, when the substrate W is returned to the processing container 51 after the rotational movement, it is favorable to ignite (generate) the plasma after increasing the temperature of the substrate W by the not-shown temperature adjuster inside the processing container 51.

Because the igniting and extinguishing (stopping) of the plasma is performed multiple times partway through the processing of one substrate W, there is a possibility that particles caused by the igniting and extinguishing of the plasma may occur inside the processing container 51.

Here, in the case where the processor 50 is the inductively coupled plasma processing apparatus, the occurrence of the particles can be suppressed by extinguishing the plasma by reducing the source voltage (the voltage of the high frequency wave generator 54a) in steps and then simultaneously switching the source voltage and the bias voltage (the voltage of the high frequency wave generator 54b) OFF (ramp-down), and by igniting the plasma by increasing the source voltage in steps and then switching the bias voltage ON (ramp-up).

In other words, in the case where the processor 50 is the inductively coupled plasma processing apparatus, ramp-down and ramp-up can be performed after discontinuing the processing. Therefore, the occurrence of the particles caused by the igniting and extinguishing of the plasma can be suppressed.

The supply of the gas to the interior of the load lock chamber 31 will now be described further.

Generally, if a pressure difference ΔP between a pressure P1 in the interior of the load lock chamber 31 and a pressure P2 in the depressurization unit 34a changes as a time T elapses, the conductance C of the exhaust system also changes according to the change of the pressure difference ΔP. However, the conductance controller 34a2 is provided in the load lock unit 30. Therefore, the conductance C of the exhaust system can be changed arbitrarily by the conductance controller 34a2.

Therefore, the conductance C of the exhaust system is controlled by the conductance controller 34a2 to cause an exhaust amount Q to be constant.

To cause the exhaust amount Q to be constant, it is sufficient for the conductance C of the exhaust system to be increased as the time T elapses.

By causing the exhaust amount Q to be constant, the pressure P1 in the interior of the load lock chamber 31 can be changed gradually without an abrupt change of the pressure P1.

If the pressure P1 in the interior of the load lock chamber 31 can be changed gradually, the particles in the interior of the load lock chamber 31 do not adhere easily to the substrate W because the particles do not float around easily.

Also, if the pressure P1 in the interior of the load lock chamber 31 can be changed gradually, the time necessary for exhausting can be reduced.

In such a case, it is sufficient for the controller 34a4 to control the conductance controller 34a2 to reduce the pressure P1 in the interior of the load lock chamber 31 based on the electrical signal transmitted from the sensor 34a3. Thus, the conductance controller 34a2 controls the conductance C of the exhaust system to cause the exhaust amount Q to be constant when exhausting the gas that is in the interior of the load lock chamber 31.

In the case where the exhaust amount Q is sensed using a not-shown sensing device, it is sufficient for the controller 34a4 to control the conductance controller 34a2 to cause the exhaust amount Q to be constant based on the output of the not-shown sensing device.

By thus performing the exhausting, the floating around of the particles also can be suppressed.

An exhaust system having a low conductance and an exhaust system having a high conductance are provided; and slow exhaust is performed using the exhaust system having the low conductance from a pressure P11 to a pressure P12. Then, when the pressure reaches P12, the exhaust system is switched to the exhaust system having the high conductance; and a full-power exhaust is performed.

The pressure P11 is the pressure when starting the exhaust (e.g., atmospheric pressure). The pressure P12 is the pressure when switching from the slow exhaust to the full-power exhaust.

Thus, because the pressure change can be gradual, the floating around of the particles in the interior of the load lock chamber 31 can be suppressed.

However, if the slow exhaust is performed, the time until the prescribed pressure is reached lengthens. Also, the electrical power amount that is necessary to perform the exhaust increases if the slow exhaust is performed.

Conversely, by performing the exhaust described above, the time to reach the prescribed pressure is reduced; and the electrical power amount necessary for the exhaust can be reduced.

Embodiments are described above. However, the invention is not limited to the description recited above.

For example, although the planar configuration of the substrate W processed by the substrate processing apparatus 1 is a quadrilateral, this is not limited thereto. The planar configuration of the substrate W may be another configuration such as a circle, a polygon, etc.

Additions, deletions, or design modifications of components or additions, omissions, or condition modifications of processes appropriately made by one skilled in the art in regard to the embodiments described above are within the scope of the invention to the extent that the spirit of the invention is included.

What is claimed is:

1. A substrate processing apparatus, comprising:
a processor performing processing of a substrate in an atmosphere, the atmosphere being depressurized from atmospheric pressure;
a transferring part transferring the substrate in an environment having a pressure higher than the pressure when performing the processing;
a load lock unit provided between the processor and the transferring part; and
a transfer unit provided between the load lock unit and the processor,
the load lock unit including
a supporter supporting the substrate, and
a drive unit moving a position in a rotation direction of the supporter,
the transfer unit transferring the substrate from the processor to the supporter partway through the processing of the substrate in the processor,
the drive unit moving a position in a rotation direction of the transferred substrate.

2. The apparatus according to claim 1, a planar configuration of the substrate is a quadrilateral, wherein the drive unit moves the position 90°×n (n being a natural number) in the rotation direction of the transferred substrate.

3. The apparatus according to claim 1, wherein the drive unit moves, when transferring the substrate between the transferring part and the supporter, the position in the rotation direction of the transferred substrate to cause an extension direction of a side of the substrate transferred to the supporter to be parallel or perpendicular to a transfer direction of the transferring part.

4. The apparatus according to claim 1, wherein the drive unit moves, when transferring the substrate between the transfer unit and the supporter, the position in the rotation direction of the transferred substrate to cause an extension direction of a side of the substrate transferred to the supporter to be parallel or perpendicular to a line connecting a center of the transfer unit and a center of a region where the supporter is provided.

5. A substrate processing method, comprising:
performing processing of a substrate in a first environment depressurized from atmospheric pressure;
moving the substrate from the first environment to a second environment partway through the processing of the substrate; and
moving a position in a rotation direction of the substrate in the second environment,
the second environment being separated from the first environment and having a pressure not more than a pressure of the first environment.

6. The method according to claim 5, a planar configuration of the substrate is a quadrilateral wherein the moving of the position in the rotation direction of the substrate moves the position 90°×n (n being a natural number) in the rotation direction of the substrate.
